(19) United States
(12) Patent Application Publication
(10) Pub. No.: US 2007/0090084 A1
(43) Pub. Date: Apr. 26, 2007

(54) Reclaim method for extreme ultraviolet lithography mask blank and associated products

(76) Inventors: Pei-Yang Yan, Saratoga, CA (US); Yan Borodovsky, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/255,673

(22) Filed: Oct. 20, 2005

(51) Int. Cl. C23G 1/00; H01B 13/00; C23F 1/00; H05K 1/00; B44C 1/22

(52) U.S. Cl. 216/13; 174/250; 134/2; 216/41

(57) ABSTRACT

A reclaim method for an extreme ultraviolet mask blank and associated products are generally described. In this regard, according to one example embodiment, a reclaim method comprises removing an outer capping layer from a multilayer (ML) stack, the ML stack having been deposited on an inner capping layer, removing the ML stack, and depositing a new ML stack on the inner capping layer, the inner capping layer having an inner thickness that is selected to enable constructive interference between the new ML stack and a ML reflector beneath the inner capping layer.

### TECHNICAL FIELD

Embodiments of the present invention are generally directed to the field of semiconductor fabrication and, more particularly, to lithography.

### BACKGROUND

Extreme ultraviolet lithography (EUVL) is a new generation lithography that uses extreme ultraviolet (EUV) radiation with a wavelength that may be in the range of 10 to 14 nanometer (nm) to carry out projection imaging. The EUVL system may use reflective optics and masks in which the image is formed in an absorbing metal.

EUVL masks may be patterned from multilayer (ML) mask blanks. To achieve good image quality and high wafer yields, mask blanks must be manufactured without defects. Due to high degree of accuracy and minimal defect requirements, these ML mask blanks are expensive. Current techniques to fabricate ML mask blanks are for one-time use only. After the mask blank is used for mask patterning, it is usually discarded. Reclaiming the ML blanks with the current design is impossible without sacrificing the quality of the mask.

### BRIEF DESCRIPTION OF THE DRAWINGS

Embodiments of the present invention are illustrated by way of example, and not by way of limitation, in the figures of the accompanying drawings in which like reference numerals refer to similar elements and in which:

FIG. 1 is a diagram illustrating a system in which one embodiment of the invention can be practiced;

FIG. 2 is a diagram illustrating a reflective mask according to but one embodiment;

FIG. 3 is a diagram illustrating a reusable coating according to but one embodiment;

FIG. 4A is a diagram illustrating a reusable coating having three alternating layers in the ML stack according to but one embodiment;

FIG. 4B is a diagram illustrating a reusable coating having five alternating layers in the ML stack according to but one embodiment;

FIG. 4C is a diagram illustrating a reusable coating having seven alternating layers in the ML stack according to but one embodiment;

FIG. 5 is a diagram illustrating a process to fabricate a reusable mask blank according to but one embodiment;

FIG. 6 is a diagram illustrating a process to reuse the mask blank according to but one embodiment; and

FIG. 7 is a diagram illustrating a process to reuse the mask blank multiple times according to but one embodiment.

### DETAILED DESCRIPTION

Embodiments of a reclaim method for an extreme ultraviolet lithography mask blank and associated products are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the invention.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

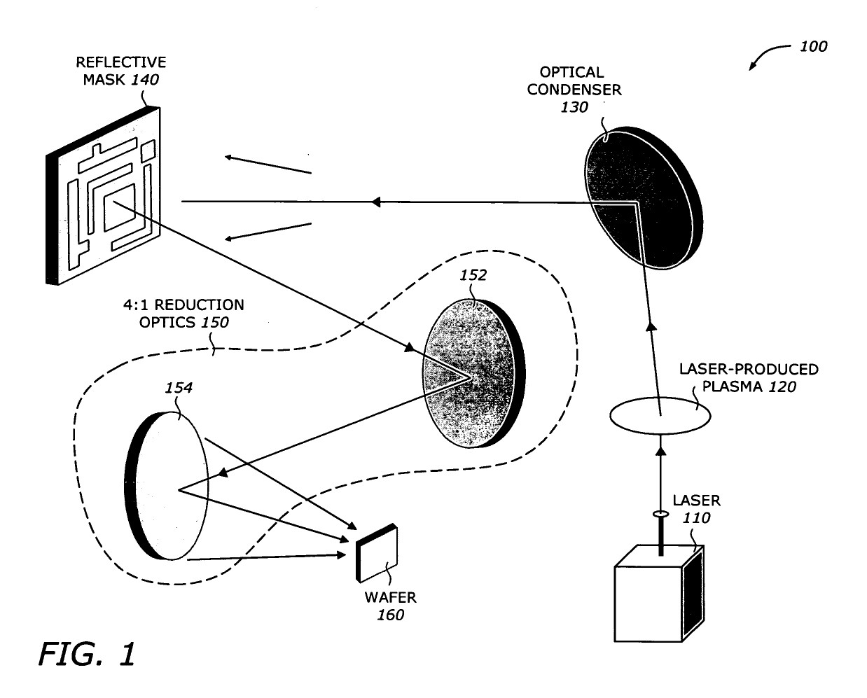

FIG. 1 is a diagram illustrating a system 100 in which a reclaimable mask blank may be used. The system 100 includes a laser 110, laser-produced plasma 120, an optical condenser 130, a reflective mask 140, reduction optics 150, and a wafer 160.

The laser 110 may generate a laser beam to bombard a target material, which may produce plasma 120 with a significant broadband extreme ultra-violet (EUV) radiation. The optical condenser 130 may collect the EUV radiation through mirrors coated with EUV interference films. The optical condenser 130 may then illuminate the reflective mask 140 with EUV radiation. The EUV radiation may be 13 nm wavelength radiation.

The reflective mask 140 may have an absorber pattern across its surface. The pattern may be imaged at 4:1 demagnification by the reduction optics 150. Other demagnification ratios are possible. The reduction optics 150 may include mirrors such as mirrors 152 and 154. These mirrors, for example, may be aspherical with tight surface figures and roughness (e.g., less than 3 Angstroms). The wafer 160 may be resist-coated and may be imaged by the pattern on the reflective mask 140. Typically, a step-and-scan exposure may be performed, i.e., the reflective mask 140 and the wafer 160 are synchronously scanned. Using this technique, a resolution less than 50 nm may be possible.

The reflective mask 140 may have a re-usable mask blank which can be reclaimed after a first use. Because construction of the reflective mask is expensive, particularly a defect-free mask, discarding a used mask is wasteful. In one embodiment, a reclaim method allows a mask blank to be re-used after a first use. A first use may comprise the time during which a mask blank is used before a first reclaim to the time it is reclaimed. In an embodiment, a reclaim method may provide for multiple re-uses of a mask blank. A reclaim method may provide for multiple re-uses of a mask blank by a re-deposition technique. Note that the diagrams shown in the figures are for illustrative purposes only. The dimensions are not scaled.

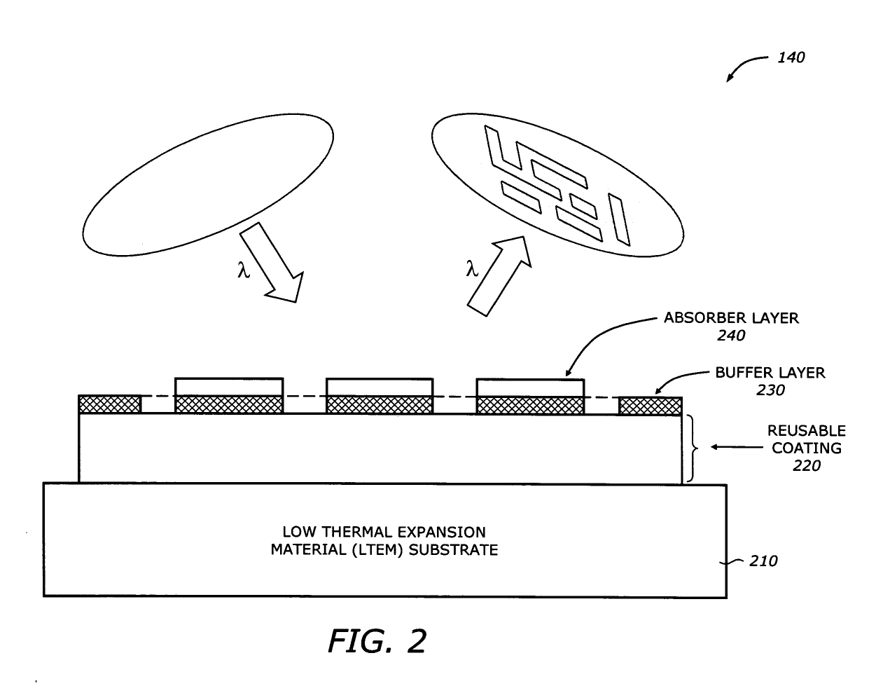

FIG. 2 is a diagram illustrating a reflective mask 140 according to one embodiment. The reflective mask 140 may include a substrate 210, a re-usable coating 220, a buffer layer 230, and an absorber layer 240.

The substrate 210 may be made of a material that has a low coefficient of thermal expansion (CTE). A low CTE may provide stability against temperature changes. A typical CTE may be +/−30 parts per billion (ppb)/° C. over a temperature range of 5° C. to 35° C. Other ranges (ppb) are possible for less typical CTE's. Other properties of the substrate 210 may include stability against crystallization, thermal cycling, and mechanical cycling. In one embodiment, the substrate material may be ULE (ultra low expansion) glass manufactured by Corning Incorporated.

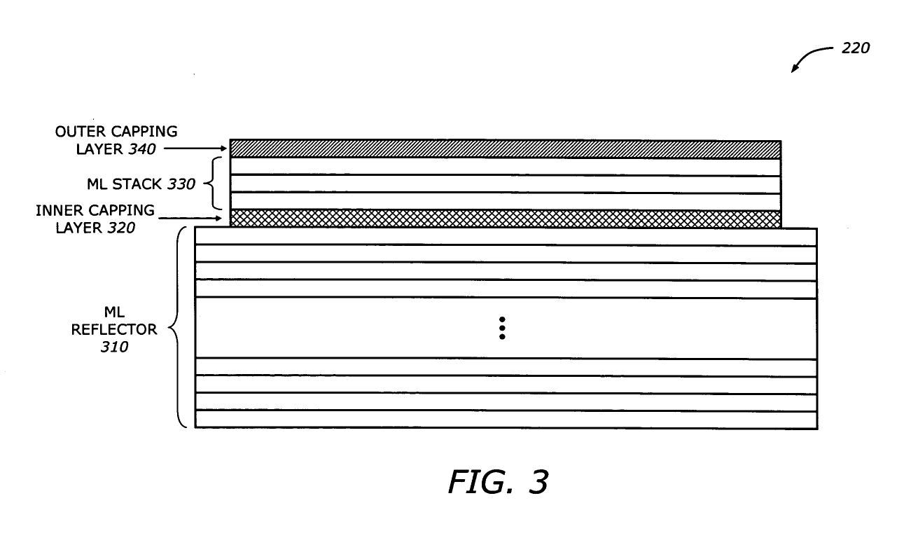

The re-usable coating 220 may provide high reflectivity for the image projection. The re-usable coating 220 may be re-used after a first use. In an embodiment, re-usable coating 220 may be re-used multiple times by a blank reclaim method comprising removal and re-deposition of elements of re-usable coating 220. The re-usable coating 220 will be described in more detail in FIG. 3.

The buffer layer 230 may facilitate the etching and repair of the absorber layer 240. Buffer layer 230 may be a buried silicon oxide and may have a thickness of approximately 20 nm to 100 nm. A buffer layer 230 may not be necessary in some applications. The absorber layer 240 may allow a pattern to be formed through lithography.

FIG. 3 is a diagram illustrating a re-usable coating 220 according to one embodiment. The re-usable coating may include a multilayer (ML) reflector 310, an inner capping layer 320, a ML stack 330, and an outer capping layer 340.

The ML reflector 310 may provide high reflectivity for the imaging process. ML reflector 310 may consist of a large number of alternating layers of materials having dissimilar optical constants for EUV radiation. These alternating layers may provide a resonant reflectivity when the period of the layers is approximately λ/2. For example, for λ=13 nm, a period of 6.5 nm may be used. In typical embodiments, the ML reflector 310 may be made of between 40 and 50 pairs of alternating layers of Molybdenum (Mo) and Silicon (Si).

The inner capping layer (ICL) 320 may provide protection for the ML reflector 310. In an embodiment, the ICL 320 may be made of a relatively chemically inert material. The difference between the refractive indices of the material for the inner capping layer 320 and the adjacent layer is typically high. In one embodiment, the material is one of gold (Au), baron nitride (BN), carbon (C), palladium (Pd), platinum (Pt), rhodium (Rh), ruthenium (Ru), silicon (Si), silicon carbide (SiC), boron carbide (B₄C), silicon oxide (SiO₂), and titanium nitride (TiN). Other potential materials may include transition-metal borides, carbides and nitrides, boron carbide and alumina. The thickness hᵢ of the inner capping layer 320 may be selected to enable the constructive interference between the ML stack 330 and the ML reflector 310. The ICL 320 may also include more than one inner layer to provide more protection to the ML reflector during blank reclaiming and mask patterning.

The ML stack 330 may include a stack of alternating layers of different materials. Typical materials for the alternating layers include Mo and Si. Other materials may include gold (Au), baron nitride (BN), carbon (C), palladium (Pd), platinum (Pt), rhodium (Rh), ruthenium (Ru), silicon (Si), silicon carbide (SiC), boron carbide (B₄C), silicon oxide (SiO₂), and titanium nitride (TiN). The ML stack 330 and the ML reflector 310 may form constructive, or additive, interference or destructive, or subtractive, interference. To optimize or improve the overall reflectivity for the first and subsequent uses, the thickness hᵢ of the inner capping layer 320 may be selected to enable, improve, optimize, or maximize this constructive interference between ML stack 330 and the ML reflector 310. Through extensive simulations, this thickness may be obtained for a variety of configurations of the ML stack and other parameters. Typically, the construction of the ML stack 330 is the same as that of the ML reflector 310; i.e., the ML stack 330 forms constructive interference of scattered radiation. If the same two materials (e.g., Mo and Si) used in the ML reflector 310 are also used in the ML stack 330, then the bi-layer period and the ratio of one material thickness to the bi-layer period in the ML stack 330 is approximately the same to that of ML reflector 310. When different materials are used in the ML stack 330, the period and the ratio are adjusted depending upon the indices of refraction of the materials. Forming constructive interference of the scattered radiation by the ML stack 330 is desirable.

In an embodiment, the inner capping layer 320 and the ML stack 330 may form N pairs of layers where N is a positive integer. The value of N and the thickness of the alternating layers in the ML stack 330 may be selected according to the damage level incurred after the first use of the reflective mask 140, or may be selected according to ML reclaim process margin control. The damage level may be a function of the mask process, cleaning, and usage and may vary from case to case. In one embodiment, N is between one and four.

The outer capping layer 340 may provide protection for the ML stack 330. Outer capping layer 340 may be made of material similar to the inner capping layer 320. However, the material and thickness of the outer capping layer 340 may not necessarily be the same as those of the inner capping layer 320.

The re-usable coating 220 may be designed for more than one time use. According to one embodiment, in the first use, the re-usable coating 220 is used with the inner capping layer 320, the ML stack 330, and the outer capping layer 340. After the mask is used, the outer capping layer 340 and the ML stack 330 may be removed, for example, by etching and cleaning, leaving the inner capping layer 320 and the ML reflector 310 intact to be used as a mask blank again.

Alternatively, according to an embodiment, after the mask is used and the outer capping layer 340 and the ML stack 330 are removed, leaving the inner capping layer 320 and the ML reflector intact, a new ML stack 330 and new outer capping layer 340 may be re-deposited on the inner capping layer 320 to be re-used as a mask blank.

In an embodiment, multiple re-uses of a mask blank are envisioned where after each mask use, the removal of the outer capping layer 340 and the ML stack 330 is followed by re-deposition of a new outer capping layer 340 and a new ML stack 330. Such process may be repeated for each mask use allowing multiple reclaim and re-use of a mask blank. Such multiple reclaim of a mask blank may provide many advantages including significantly reducing fabrication costs associated with using EUVL masks.

Several embodiments are possible to provide improved reflectivity for first use and subsequent use of mask blank. Let R₁ and R₂ be the reflectivities of the mask blank at the first use and second use, respectively. In the embodiments described below, the re-usable coating 220 will be labeled 401, 402, and 403. It is shown that the construction of the embodiments is such that R₁ and R₂ are approximately the same, indicating that the second use is almost as good as the first use. Multiple uses beyond the second use in accordance with embodiments described herein are expected to provide similar results.

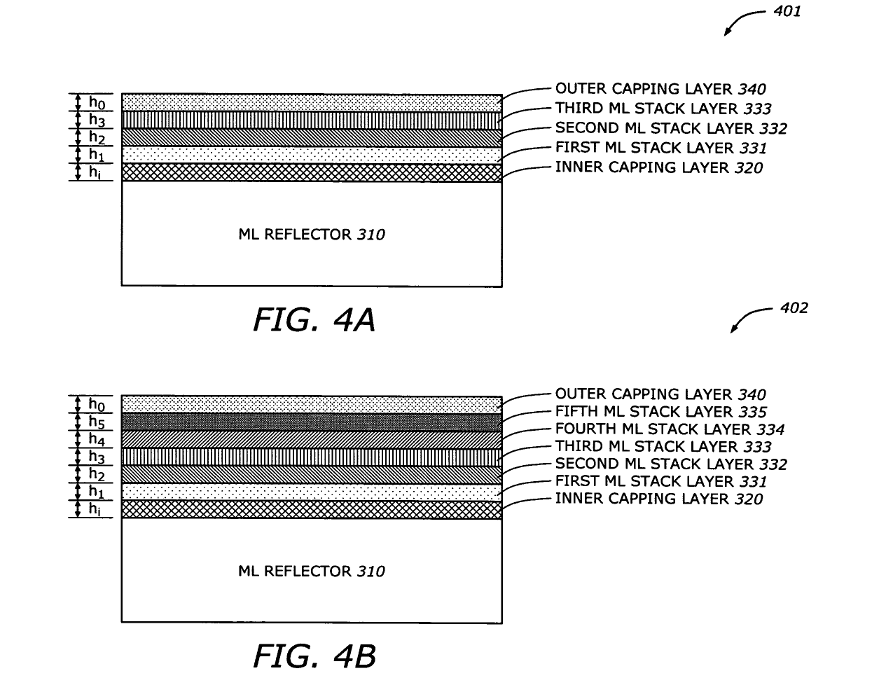

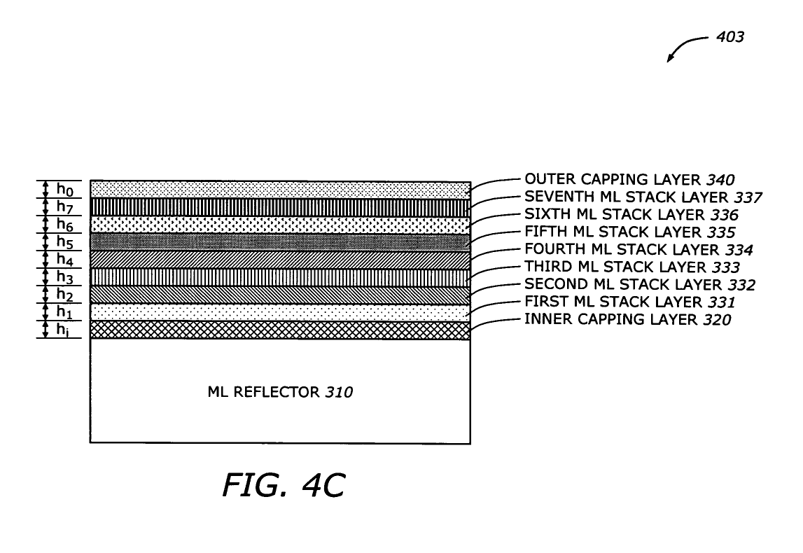

FIG. 4A is a diagram illustrating a reusable coating 401 having three alternating layers in the ML stack according to one embodiment. In the example of FIG. 4A, the re-usable coating 401 has the inner capping layer (ICL) 320, a first ML stack layer 331, a second ML stack layer 332, a third layer 333, and the outer capping layer (OCL) 340.

The ICL 320 and the ML stack layers form two pairs (N=2). Let R₁ and R₂ be the reflectivities (in percentage) at the first and second uses, respectively. Let hᵢ, h₁, h₂, h₃, and h₀ be the thickness (in nm) and mᵢ, m₁, m₂, m₃, and m₀ be the material of the ICL 320, the first ML stack layer 331, the second ML stack layer 332, the third ML stack layer 333, and the outer capping layer (OCL) 340, respectively. Table 1 shows R₁ and R₂ and the corresponding for an example embodiment.

TABLE 1

| Case | hᵢ mᵢ | h₁ m₁ | h₂ m₂ | h₃ m₃ | hₒ mₒ | R₁ | R₂ |
|---|---|---|---|---|---|---|---|
| 1 | 2Ru | 4.8Si | 2.76Mo | 4.14Si | 2Ru | 74.87 | 75.13 |
| 2 | 3Ru | 3.65Si | 2.76Mo | 3.85Si | 3Ru | 73.20 | 73.56 |
| 3 | 5.94Si | 2.76Mo | 4.14Si | 2.76Mo | 10Si | 71.39 | 72.42 |

As shown in Table 1, the differences in reflectivity between the first and second uses are 0.34%, 0.48%, 1.4% for cases 1, 2, and 3, respectively. This indicates that the reflectivity of the mask blank at the first use is almost the same as at the second use. Other materials and thicknesses may result in different reflectivities.

FIG. 4B is a diagram illustrating a re-usable coating 402 having five alternating layers in the ML stack according to one embodiment. In the example of FIG. 4B, the re-usable coating 402 has 5 ML stack layers in addition to the ICL 320 and the OCL 340. The five ML stack layers are first, second, third, fourth, and fifth ML stack layers 331, 332, 333, 334, and 335, respectively.

The ICL 320 and the ML stack layers form three pairs (N=3). Table 2 shows R₁ and R₂ and the corresponding thickness and materials for an example embodiment. The notations are the same as those in Table 1 with the addition of h₄, h₅, m₄, and m₅ as the thickness and materials of the fourth and fifth ML stack layers 334 and 335, respectively.

TABLE 2

| Case | h_{I} mᵢ | h₁ m₁ | h₂ m₂ | h₃ m₃ | h₄ m₄ | h₅ m₅ | hₒ mₒ | R₁ | R₂ |
|---|---|---|---|---|---|---|---|---|---|
| 1 | 2Ru | 4.8Si | 2.76Mo | 4.14Si | 2.76Mo | 4.14Si | 2Ru | 75.00 | 75.13 |
| 2 | 3Ru | 3.65Si | 2.76Mo | 3.85Si | 2.76Mo | 3.85Si | 3Ru | 73.37 | 73.56 |
| 3 | 5.94Si | 2.76Mo | 4.14Si | 2.76Mo | 4.14Si | 2.76Mo | 10Si | 71.63 | 72.42 |

As shown in Table 2, the differences in reflectivity between the first and second cases are 0.17%, 0.25%, and 1.09% for cases 1, 2, and 3, respectively. These numbers show that the first use is almost the same as the second use. Other thicknesses and materials may result in different reflectivities.

FIG. 4C is a diagram illustrating a re-usable coating 403 having seven alternating layers in the ML stack according to one embodiment. In the example of FIG. 4C, the re-usable coating 403 has 7 ML stack layers in addition to the ICL 320 and the OCL 340. The seven ML stack layers are first, second, third, fourth, fifth, sixth, and seventh ML stack layers 331, 332, 333, 334, 335, 336 and 337, respectively.

In an embodiment, the ICL 320 and the ML stack layers form 4 pairs (N=4). Table 3 shows R₁ and R₂ and the corresponding thickness and materials for an example embodiment. The notations are the same as those in Table 2 with the addition of h₆, h₇, m₆, and m₇ as the thickness and materials of the sixth and seventh ML stack layers 336 and 337, respectively.

TABLE 3

| Case | h_{I} mᵢ | H₁ m₁ | h₂ m₂ | h₃ m₃ | H₄ m₄ | h₅ m₅ | h₆ m₆ | h₇ m₇ | hₒ mₒ | R₁ | R₂ |
|---|---|---|---|---|---|---|---|---|---|---|---|
| 1 | 2Ru | 4.8Si | 2.76Mo | 4.14Si | 2.76Mo | 4.14Si | 2.76Mo | 4.14Si | 2Ru | 75.11 | 75.13 |
| 2 | 3Ru | 3.65Si | 2.76Mo | 3.85Si | 2.76Mo | 4.14Si | 2.46Mo | 3.85Si | 3Ru | 73.54 | 73.56 |
| 3 | 5.94Si | 2.76Mo | 4.14Si | 2.76Mo | 4.14Si | 2.76Mo | 4.14Si | 2.76Mo | 10Si | 71.84 | 72.42 |

As shown in Table 3, the differences in reflectivity between the first and second uses are 0.02%, 0.02%, and 0.8% for cases 1, 2, and 3, respectively. These numbers show that the first use in almost the same as the second use. Other thicknesses and materials may result in different reflectivities.

Table 4 shows a set of re-useable ML designs with two, three, four, and five different layers of ML stacks and a triple ICL according to one embodiment. In the example in Table 4, the triple ICL consists of three layers: 2 nm Ru, 11.5 nm Si, and 2 nm Ru. During the blank reclaiming and mask patterning for the second use, if the top inner Ru capping layer is punched through, the underneath Si layer may continue protect the ML reflector. If the Si layer is further punched through, the underneath Ru layer may continue protect the ML reflector. In both cases, there may be very little reflectivity impact to the reclaimed ML blank. In one embodiment, the top inner Ru capping and Si layer underneath may be removed away, leaving the other Ru layer as a capping layer.

TABLE 4

| | Triple ICL | | | | | | | | | | |
|---|---|---|---|---|---|---|---|---|---|---|---|
| Case | (hᵢ mᵢ) | | | h₁ m₁ | h₂ m₂ | h₃ m₃ | h₄ m₄ | h₅ m₅ | hₒ mₒ | R₁ | R₂ |
| 1 | 2Ru | 11.5Si | 2Ru | 4.8Si | 2.76Mo | 11Si | | | | 70.53 | 71.95 |
| 2 | 2Ru | 11.5Si | 2Ru | 4.8Si | 2.76Mo | 4.14Si | 2Ru | | | 73.44 | 73.24 |
| 3 | 2Ru | 11.5Si | 2Ru | 4.8Si | 2.76Mo | 4.14Si | 2.76Mo | 11Si | | 70.88 | 71.95 |
| 4 | 2Ru | 11.5Si | 2Ru | 4.8Si | 2.76Mo | 4.14Si | 2.76Mo | 4.14Si | 2Ru | 73.76 | 73.24 |

Note that in Table 4, the outer capping layer 340 is 11 nm Si, 2 nm Rn, 11 nm Si, 2 nm Ru for cases 1, 2, 3, and 4, respectively according to one embodiment.

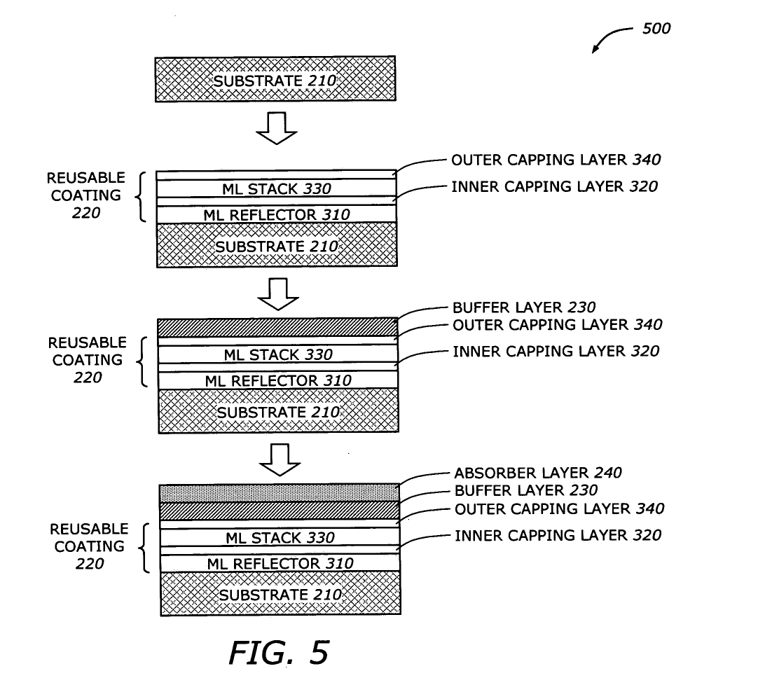

FIG. 5 is a diagram illustrating a process 500 to fabricate a reusable mask blank according to one embodiment.

The process 500 may start with formation and qualification of the substrate 210. Next, the re-usable coating 220 may be deposited. Defect inspection may be carefully performed to ensure that a blank meets defect standards with high quality reflection. The re-usable coating 220 may be deposited by depositing the pairs of layers of the ML reflector 310, the inner capping layer 320, the ML stack layers of the ML stack 330, and optionally the outer capping layer 340, in that order.

Next, buffer layer 230 may be deposited. Then, the absorber layer 240 may be deposited. At this time, the complete re-usable mask blank is ready for the first use.

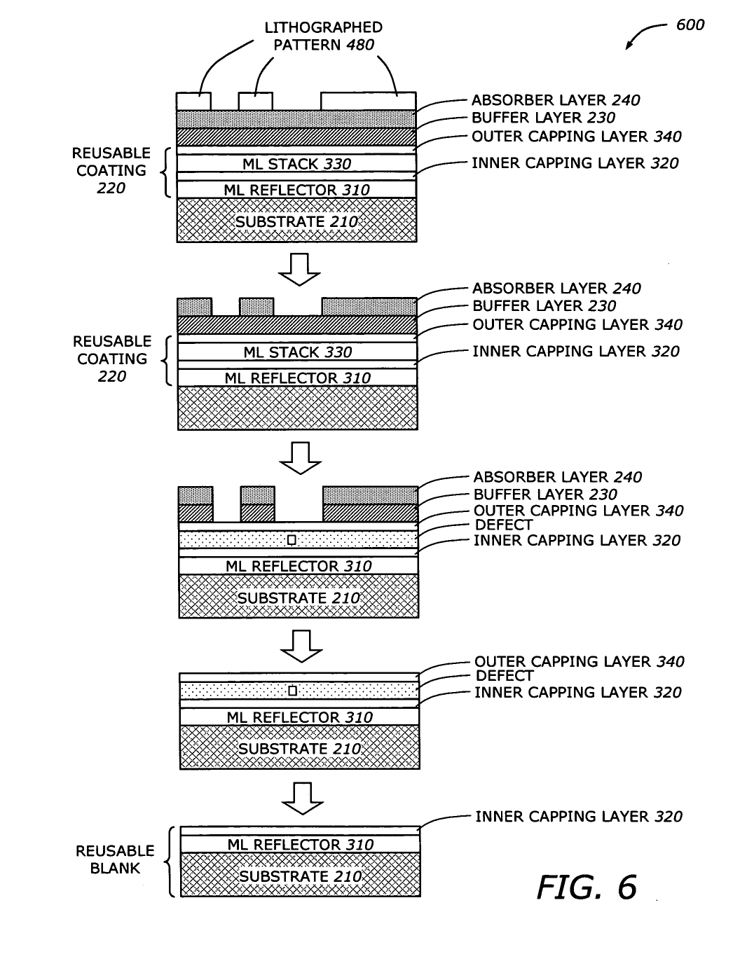

FIG. 6 is a diagram illustrating a process 600 to reuse the mask blank according to one embodiment.

The process 600 may start by creating a lithographic pattern 480. Next, this lithographic pattern may be transferred to the absorber layer 240. The absorber layer 240 may be etched according to the pattern. At this time, defect inspection and absorber repair may be performed.

Then, the buffer layer 230 may be etched away according to the pattern. Additional inspection and repair may be performed to ensure compliance with defect standards and high quality reflection. The imaging process may then be performed.

Defects may occur in the ML stack 330 and/or the capping layer 340 during an initial deposition or subsequent redeposition process. The outer capping layer 340 and the ML stack 330 may be removed, for example, by etching, leaving the inner capping layer 320, the ML reflector 310, and the substrate 210 intact. The inner capping layer 320, the ML reflector 310, and the substrate 210 may form a new mask blank ready for subsequent use.

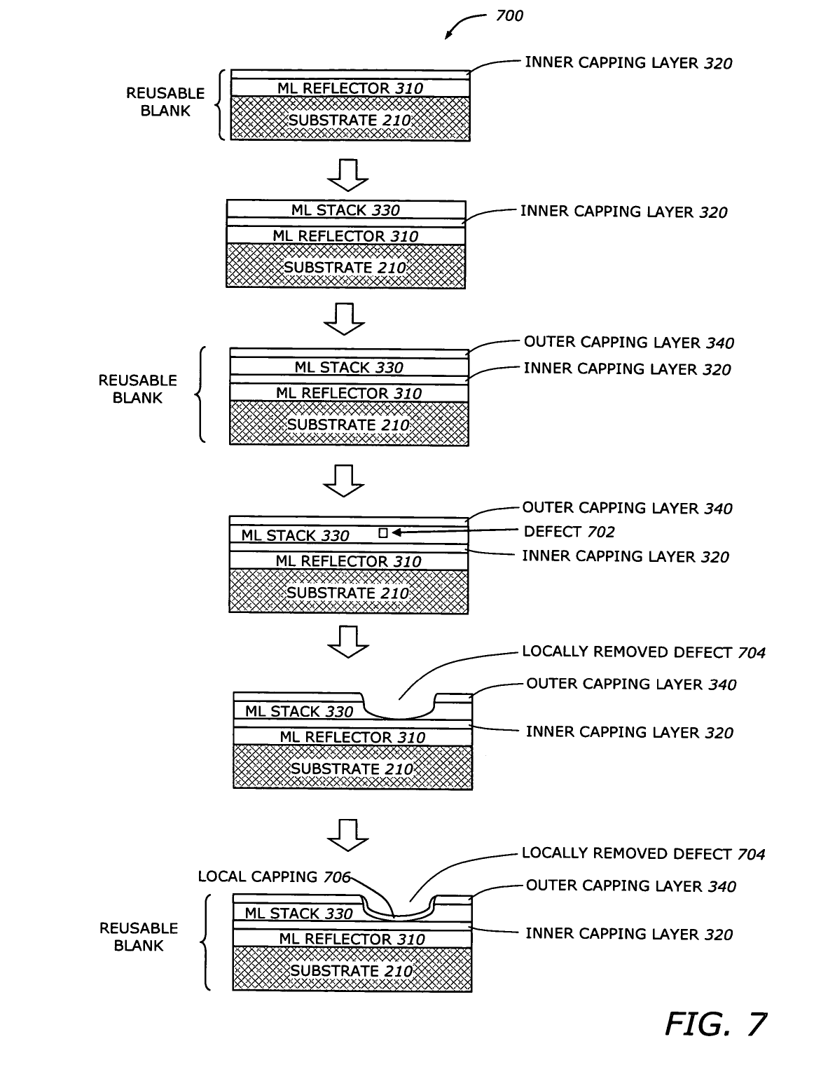

FIG. 7 is a diagram illustrating a process 700 to reuse the mask blank multiple times according to one embodiment.

A re-usable blank, which may be similar to the final product in process 600, comprising a substrate 210, an ML reflector 310, and inner capping layer 320 may be prepared for re-deposition. Preparation may include cleaning, inspection, and re-qualification of the re-usable blank. In one embodiment, manufacturing equipment may receive a re-usable blank in preparation for re-deposition.

In an embodiment, a new ML stack 330 may be re-deposited on the inner capping layer 320. Subsequently, a new outer capping layer 340 may be re-deposited on the new ML stack 330. Such product may be ready for re-use as a mask blank.

In one embodiment, new ML stack 330 may comprise 1-3 pairs of alternating layers of Mo/Si. Other suitable materials for the new ML stack may include gold (Au), baron nitride (BN), carbon (C), palladium (Pd), platinum (Pt), rhodium (Rh), ruthenium (Ru), silicon (Si), silicon carbide (SiC), boron carbide (B₄C), silicon oxide (SiO₂), and titanium nitride (TiN). The number of layers in the new ML stack 330 may depend on the extent of damage incurred after a first use (i.e.—due to mask process, cleaning, usage).

Multiple iterations of depositing new inner capping layer(s) 320 and new ML stack(s) 330 are envisioned for process 700. According to one embodiment, the new inner capping layer(s) 320 and the new ML stack(s) form N pairs, where N is a positive integer and is selected according to mask usage. In one embodiment, N is between one and four.

The inner capping layer(s) 320 may have an inner thickness that is selected to enable constructive interference between the new ML stack(s) 330 and the ML reflector 310 beneath the inner capping layer(s) 320. The thickness of any adjacent layer to the inner capping layer(s) 320 may be selected to maximize reflectivity of the ML reflector 310 and the new ML stack(s) 330. The thickness of the new ML stack 330 may be selected to enable constructive interference between the new ML stack 300 and the ML reflector 310 beneath the inner capping layer(s) 320.

In one embodiment, it is possible that a defect 702 in the new ML stack 330 and/or new outing capping layer 340 may occur (during re-deposition for example). However, defects in the ML stack 330 such as defect 702 are shallow amplitude defects and may be locally repaired unlike deep embedded phase defects that may occur in the ML reflector 310. For example, defect 702 may be removed by a local etch process 704. A local capping layer 706 may be locally deposited into the small crater 704 made during defect removal to cover any exposed ML stack 330. Preferentially, the local capping layer 706 comprises a material with a lower etch selectivity than the material of the new outer capping layer 340 or, in other words, a material which has etch selectivity to the material of the new outer capping layer 340 to prevent damage to any underlying capping layer 320 during subsequent etching.

Locally repaired region 704, 706 may leave a very shallow crater that negligibly impacts wafer printing. When the mask blank is re-claimed again for multiple re-use, i.e.—by performing processes 600 and 700 in succession, the probability of a deposition defect occurring in the same repair region 704, 706 is very small. Such product of process 700 with locally repaired region 704, 706 may be a reusable blank suitable for multiple re-use.

Repeating processes 600 and 700 on a mask blank may provide unlimited re-uses of a mask blank without sacrificing the blank performance. The re-deposition and repair of process 700 may allow repeated re-uses of a mask blank beyond that which is permitted by using process 600 alone. Process 600 alone may limit blank re-uses to the number of embedded inner capping layers 320. After all capping layers 320 are removed, by etching for example, the mask blank may not be re-used if only process 600 is used. Using reclaim process 600 alone to achieve a higher number of re-uses may require a higher number of embedded capping layers 320. For higher numbers of embedded capping layers, there may be an increased reflectivity loss and increased risk of adding a deposition defect to the ML stack 330. Reclaim method 700 may enable multiple reclaim and re-use of a mask blank with only one capping layer 320 by re-deposition and repair. Such method 700 may enable avoidance of higher numbers of embedded capping layers and associated reflectivity loss and defect risks.

The re-usable mask blank product(s) of method 700 may undergo further processing in preparation for use. An absorber layer may be deposited on the new outer capping layer. An anti-reflective coating may be deposited on the absorber layer. Lithographic patterning may be used to selectively pattern the absorber layer with a desired image. A prepared mask may be coupled to a piece of manufacturing equipment, such as a lithography scanner, to manufacture semiconductor products such as Integrated Circuit (IC) chips. A prepared mask may be used as a reflective mask 140 in a system 100 as depicted in FIG. 1.

Various operations may be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. A reclaim method comprising:
removing an outer capping layer from a multilayer (ML) stack, the ML stack having been deposited on an inner capping layer;
removing the ML stack to leave the inner capping layer; and
depositing a new ML stack on the inner capping layer, the inner capping layer having an inner thickness that is selected to enable constructive interference between the new ML stack and a ML reflector beneath the inner capping layer.

2. A method according to claim 1, further comprising:
depositing a new outer capping layer on the new ML stack.

3. A method according to claim 2, further comprising:
locally removing defects in the new outer capping layer and the new ML stack; and
locally depositing a repair capping layer in the region where defects have been locally removed.

4. A method according to claim 3, wherein locally depositing a repair capping layer comprises using a repair capping material with a lower etch selectivity than the material of the new outer capping layer.

5. A method according to claim 1, further comprising:
cleaning the inner capping layer before depositing a new ML stack on the inner capping layer.

6. A method according to claim 2, further comprising:
depositing an absorber layer on the new outer capping layer;
depositing an anti-reflective coating on the absorber layer; and
patterning the absorber layer.

7. A method according to claim 1, wherein depositing a new ML stack on the inner capping layer comprises:
depositing one to three pairs of alternating layers comprising Mo and Si.

8. A method according to claim 1, wherein depositing a new ML stack on the inner capping layer comprises:
depositing a new ML stack such that the ML stack and the inner capping layer form N pairs, N being a positive integer and selected according to mask usage.

9. A method according to claim 8, wherein depositing a new ML stack further comprises selecting N between one and four.

10. A method according to claim 1, wherein depositing the new ML stack comprises depositing at least one layer having material made by one of gold (Au), baron nitride (BN), carbon (C), palladium (Pd), platinum (Pt), rhodium (Rh), ruthenium (Ru), silicon (Si), silicon carbide (SiC), molybdenum (Mo), boron carbide (B₄C), silicon oxide (SiO₂), and titanium nitride (TiN).

11. A method according to claim 2, wherein depositing a new outer capping layer comprises depositing at least one layer having material made by one of gold (Au), baron nitride (BN), carbon (C), palladium (Pd), platinum (Pt), rhodium (Rh), ruthenium (Ru), silicon (Si), silicon carbide (SiC), molybdenum (Mo), boron carbide (B₄C), silicon oxide (SiO₂), and titanium nitride (TiN).

12. The method of claim 2 wherein at least one of the inner and outer capping layers comprises a material with a refractive index highly different than an adjacent refractive index of an adjacent layer.

13. A product fabricated by the method of claim 1.

14. A product fabricated by the method of claim 2.

15. A product fabricated by the method of claim 3.

16. A product fabricated by the method of claim 6.

17. A product fabricated by the method of claim 6 coupled to integrated circuit manufacturing equipment.

18. A reclaim method comprising:
removing an outer capping layer from a multilayer (ML) stack, the ML stack having been deposited on an inner capping layer;
removing the ML stack to leave the inner capping layer; and
depositing a new ML stack on the inner capping layer, the new ML stack having a thickness that is selected to enable constructive interference between the new ML stack and a ML reflector beneath the inner capping layer.

19. A method according to claim 18, further comprising:
depositing a new outer capping layer on the new ML stack.

20. A method according to claim 19, further comprising:
locally removing defects in the new outer capping layer and the new ML stack; and
locally depositing a repair capping layer in the region where defects have been locally removed.

21. A product fabricated by the method of claim 18.

22. A product fabricated by the method of claim 19.

23. A product fabricated by the method of claim 20.
